(19) United States
(12) Patent Application Publication
(10) Pub. No.: US 2006/0257669 A1
(43) Pub. Date: Nov. 16, 2006

(54) Method of producing transparent titanium oxide coatings having a rutile structure

(76) Inventors: Arnd Ritz, Heinsberg (DE); Michael Vergöhl, Cremling Destedt (DE); Berno Husche, Braunschweig (DE)

Correspondence Address: PHILIPS INTELLECTUAL PROPERTY & STANDARDS, P.O. BOX 3001, BRIARCLIFF MANOR, NY, 10510, US

(21) Appl. No.: 10/543,285

(22) PCT Filed: Jan. 21, 2004
(86) PCT No.: PCT/IB04/00133

§ 371 Date: Jul. 3, 2006

(30) Foreign Application Priority Data
Jan. 28, 2003 (EP) 031001696

(51) Int. Cl. B32B 17/06; B32B 9/00; B32B 19/00; C23C 16/00; C23C 14/00

(52) U.S. Cl. 428/432; 428/701; 428/702; 427/248.1; 204/192.11

(57) ABSTRACT

The invention relates to a method of producing titanium oxide coatings and also to articles, in particular lamps, lights or optical elements having said coating. In order to develop a method of the generic type such that the coating with rutile is considerably simplified, and to be able to carry it out at lower process temperatures, and also to find suitable surfaces for coating in this way, the invention proposes that the coating be deposited, with the rutile structure being obtained, on the surface of the substrate that is to be coated, at an oxygen partial pressure p which can be defined, by sputtering, at a deposition temperature of 100 to 300° C. from a titanium target.

The invention relates to a method of producing transparent titanium oxide coatings having a rutile structure, and also to articles having said coating, such as lamps, optical filter systems, in particular hot light mirrors, cold light mirrors, antireflection systems, band-pass filters, cut-off filters and low-e glazing. Articles having said coating can also be used for electrical applications, such as diffusion barriers or capacitor elements. Further applications may be beam-forming or beam-splitting devices on optical fibers or micro-optical components, for instance for selecting defined wavelength ranges or for splitting signals onto various signal paths.

It is known to provide lamps for various purposes with optical layers, that is to say to coat them. Depending on the principle of action, the complete bulb of the lamp may be covered, such as that of the known halogen energy-saving lamp having an infrared reflective coating. However, it may be necessary to cover only a precisely defined part of the lamp surface, such as in the case of headlight mirror lamps for example.

On account of the high degree of flexibility in the spectral action, multilayer interference filters are often used for the optical layers. Such multilayer interference filters consist of stacks of at least two different dielectric materials having different refractive indices. The transmission and reflection ranges of these filters are determined by the layer thicknesses of the individual layers which are made up alternately of highly refractive and weakly refractive material. Such filters may be composed of one single layer, as in the case of a very simple antireflection coating, or may be composed of several hundred layers, as in the case of a multiplexer in optical communication.

The difference in refractive index of the materials used is of particular importance for the design of such filter stacks. In general, a predefined spectral target function can be implemented better the greater this difference in refractive index. With a large difference in refractive index, for example, the number of layers in the design and the overall thickness are smaller, and this generally also leads to better production of the filters.

Besides these optical considerations, thermo-mechanical features such as phase conversions in the use temperature range and the thermal expansion coefficient of the materials compared with the substrate are of great importance for the ability of products to be produced and used.

For optical layers on lamps, in particular for lamps with a quartz bulb, SiO₂ is usually used for the weakly refractive layers on account of the almost perfect matching in terms of the thermal expansion coefficient to the wall material of the lamp and on account of the low refractive index.

For the highly refractive layers, as is known, a large number of materials can be used. Examples include Ta₂O₅, Si₃N₄ and Nb₂O₅. A particularly suitable material in this connection is TiO₂, which has the highest refractive index of the abovementioned materials. TiO₂ has, inter alia, a low temperature modification, anatase, which is stable up to around 650° C., and a high temperature modification, rutile, which is stable in the adjacent temperature range. Rutile has the considerably higher refractive index.

In optical coatings, in which modification and with which refractive index the TiO₂ exists depends on the production conditions and on the subsequent treatment. Mixtures of both modifications are also possible.

In the current layer production method, after deposition TiO₂ exists as anatase, that is to say as the more weakly refractive of the two materials. The transition to the more highly refractive high temperature phase, rutile, can be achieved by annealing above the transition temperature, either by a dedicated process step or simply by operating the lamp if the operating temperature is sufficiently high, as in the case of high-wattage HID burners.

However, this phase transition results in a particular disadvantage. This phase transition changeover is associated with changes in the lattice properties, so that the density of the material increases by about 10%. Accordingly, the layers must shrink geometrically, and this leads to layer stresses. These cause tears to arise in the filter, particularly in the case of relatively thick layer stacks having an overall thickness of more than about 1 μm, and these tears may lead to the filter being destroyed and thus to a considerable shortening of the life of the lamps.

The result is that the structure of TiO₂ which is more interesting in optical terms and in terms of solid-state physics, namely rutile, is epitaxially grown only at very high temperatures. This has the disadvantage that on the one hand a complex thermal process must be used to generate and stabilize this phase of the TiO₂; on the other hand, certain lamps are operated at very high temperatures, so that the rutile forms by itself as a phase of the TiO₂ on account of the high operating temperature of the lamp. However, this has the serious disadvantage that the “subsequent” phase transition in multilayer systems leads to crystallographic stress, which can tear the thin layers as described above. A phase transition or a change of the material properties may lead to a failure of the component, e.g. by changing the refractive index and/or the layer thickness.

On the other hand, the known method also has another drawback, namely that no substrate which cannot withstand heat treatments at 600° C. and above can be coated with the desired coating with rutile. Many plastics are thermally stable, for example, only up to a maximum temperature of 150° C.

It is thus an object of the invention to develop a coating and a method of the abovementioned type such that the coating with rutile is considerably simplified and that it is possible to carry out the coating at lower process temperatures.

This object is achieved as claimed in claim 1 by a transparent, thermally stable coating comprising titanium oxide and having a rutile structure, where, at a wavelength of 550 nm, the coating:

has a refractive index of n=2.3 to n=2.75, preferably n=2.4 to n=2.70, more preferably n=2.5 to n=2.65; and/or

after annealing in a furnace at 800° C. for 15 hours, remains transparent and/or has a refractive index of n=2.3 to n=2.75, preferably n=2.4 to n=2.70, more preferably n=2.50to n=2.65.

According to the invention, a high refractive index in the region of n=2.65 to 2.75 is most preferred. Further suitable values for n are 2.73; 2.71; 2.69 and 2.67.

The layer or coating according to the invention is substantially amorphous, preferably is amorphous, and has a rutile-like short-range order structure, with the layer preferably not having any anatase structure or having practically no anatase structure.

A further subject matter of the present invention relates to a transparent interference layer for reflecting light within a wavelength range of the transparent spectrum of 250 nm to 5000 nm, in particular 380 to 3000 nm, preferably 350 to 2500 nm, more preferably 400 to 2000 nm and even more preferably 420 to 1500 nm, with the layer having one or more first layers according to the invention and one or more second layers with a refractive index which is lower than that of the one or more first layers according to the invention, said layers being arranged alternately on a substrate, preferably a transparent substrate. Further suitable reflection ranges are 680 to 2600 nm, 800 to 2500 nm, 820 to 2450 nm and 850 to 2400 nm, with ranges of 1000-1900 nm and 1050-1800 nm being particularly preferred.

The transparent interference layer may, at a wavelength of λ=550 nm, for the one or more second layers have a refractive index of n=1.32 to n=2.0, preferably n=1.35 to n=1.80 and more preferably n=1.44 to n=1.75. Further suitable values for n are 1.40; 1.42; 1.46; 1.48 and 1.50. By way of example, the refractive index may be n=1.45 for an SiO₂ layer.

Yet another subject matter of the present invention relates to a method of producing the coating or layer, in which, in order to produce the transparent, thermally stable coating comprising titanium oxide, the coating comprising titanium oxide is deposited, with the rutile structure being obtained, on the surface of the substrate that is to be coated, at an oxygen partial pressure p which can be defined, by chemical vapor deposition, in particular sputtering, at a deposition temperature of the substrate of 20 to 300° C. from a titanium target.

Chemical vapor deposition methods which can be used according to the invention are physical chemical vapor deposition such as PVD, reactive magnetron sputtering, ion beam sputtering, ion- or plasma-assisted sputtering or else plasma impulse-assisted chemical vapor deposition PICVD and also other sputtering methods known to the person skilled in the art.

Such one or more layers according to the invention can be used to coat light means, such as lamps, suitable for illumination purposes, in particular in motor vehicles.

The titanium target that can be used according to the invention is preferably made of pure titanium. The sputtering of mixed oxide layers is possible both from 2 different metal targets, from one or more metal alloy targets and also from ceramic oxide targets. In general, the operation is carried out in an oxygen/argon atmosphere.

The statements made in the following paragraphs relate in each case only to the highly refractive layers of the interference stack. In the interference stacks, the ratio of highly refractive material to weakly refractive material depends on the design of the filter. According to the invention, however, all filters can be used which comprise more than 2 layer materials, for example at least 2 different highly refractive materials.

The rutile fraction of the coating should be at least 75% by weight, preferably >80% by weight, more preferably >85% by weight, even more preferably >90% by weight and most preferably 95% by weight −100% by weight based on the overall weight of this coating.

The titanium dioxide fraction of the coating should be at least 50% by weight, preferably >60% by weight, more preferably >70% by weight, even more preferably >80% by weight, particularly preferably >90% by weight and most preferably 95% by weight −100% by weight based on the overall weight of this coating.

Titanium oxide, referred to in the description as TiO₂, may also within the context of the invention mean TiOₓ, where x=1.9 to 2.1.

Further advantageous embodiments of the subject matter of the present invention are specified in the subdlaims.

In this way, the rutile phase or the rutile structure can be produced at a much lower temperature than in known methods. This furthermore has the advantage that substrates which cannot be heated above 200° C. can now be coated with the optically very valuable rutile. As described above, rutile has a very high refractive index.

The subject matter of the invention illustrated herein is that of making rutile usable without requiring a treatment at high temperature and while circumventing the abovementioned stability problems. For this, the invention is aimed at producing layers directly during the coating in the rutile structure and with a high refractive index.

The refractive index of the transparent coating according to the invention, at a wavelength of 550 nm:

has a value of n=2.3 to n=2.75, preferably n=2.4 to n=2.70, more preferably n=2.5 to n=2.65; and/or

after annealing in a furnace at 800° C. for 15 hours, the coating remains transparent and/or has a refractive index of n=2.3 to n=2.75, preferably n=2.4 to n=2.70, more preferably n=2.5 to n=2.65.

Unless specified otherwise, measurements have been taken at room temperature, that is to say 23° C.

Dedicated studies have shown that the purpose of the invention can be achieved by suitably selecting the process parameters during the production of the layers. As illustrated in more detail in the example of embodiment, a coating with rutile structure and accordingly high refractive index can be obtained at deposition temperatures of between, for example, 50° C. and 300° C. and with simultaneous targeted ion bombardment of the epitaxially growing layer.

Initial deposition temperatures at the start of the process which are preferred according to the invention are at most 250° C., in particular 100° C.-200° C., preferably 110-190° C., even more preferably 120° C.-180° C., yet more preferably 130° C.-170° C. and particularly preferably 140° C.-160° C.

The substrate that is to be coated may be heated before it is coated, preferably to a temperature of 100° C.-200° C. The substrate is preferably transparent. However, the substrate may also not be transparent, for example a non-transparent wafer.

During the coating, the substrate may be heated up to temperatures of, for example, up to 300° C., in particular 230° C.-270° C.

The insertion or application of the layers according to the invention into or onto articles, such as lamps, glasses, in particular insulation glazing, plastics, gas sensors, optical interference filters, optical filter systems, in particular hot light mirrors, cold light mirrors, laser mirrors, antireflection systems, band-pass filters, cut-off filters, low-e glazing and/or onto articles for electrical applications, such as electrical components, diffusion barriers or capacitor elements or lamps or components of optical information technology opens up the possibility of achieving the very high refractive index of rutile and thus associated effective and cost-saving designs. This advantage also becomes possible for products or substrates which cannot withstand a heat treatment above 200° C. Furthermore, when using the material demonstrated here in lamps with high operating temperatures, the phase transition from anatase to rutile and the associated problems for the life of the lamp do not occur.

Articles with said coating can be selected from the group comprising light means, in particular lamps, preferably suitable for use in motor vehicles, lamp housings, gas sensors, glasses, in particular insulation glazing, plastics, transparent elements, filters, lenses, mirrors, laser mirrors, in particular transparent filter systems, hot light mirrors, cold light mirrors, antireflection systems, band-pass filters, cut-off filters, low-e glazing and/or articles for electrical applications, such as electrical components, in particular diffusion barriers and/or capacitor elements.

In another advantageous refinement, it is specified that, at the chosen temperatures, the crystallization of TiO₂ to the anatase phase is purposefully avoided or considerably reduced by the setting of a suitable sputtering power density and by the ion bombardment on the epitaxially growing layer.

The sputtering power density is defined as the coupled-in process power standardized to the target area used.

Furthermore, it is advantageous that the sputtering power and/or the temperature is varied such that, under the process conditions which can then be reproduced and the nature of the substrate, the anatase phase is purposefully avoided, in favor of a predominantly amorphous and particularly preferably completely amorphous rutile short-range order phase structure.

To achieve a coating having a, preferably pure, rutile phase, the sputtering power density is 9-15 W/cm² and particularly preferably 11-12 W/cm². The sputtering power density may be 1 W/cm²-40 W/cm².

Advantageously, the set oxygen partial pressure is p≦100 MPa. Oxygen partial pressures that are suitable according to the invention may be 6-10 MPa and particularly preferably ≦8 MPa. Further oxygen partial pressures that are suitable according to the invention are 3-40 MPa, 4-20 MPa and particularly preferably 5-12 MPa.

In another advantageous refinement, it is specified that, at the chosen temperature, the crystallization of TiO₂ to the anatase phase can purposefully be avoided or is considerably reduced by the setting of a suitable sputtering power at the sputtering power density and by the ion bombardment on the epitaxially growing layer.

The result is that the sputtering power density of the sputtering device can be varied such that, under the process conditions which can then be reproduced and the nature of the substrate, the anatase phase is purposefully avoided or considerably reduced, in favor of the rutile phase.

For the effective oxidation of the sputtered titanium, it is provided that the oxygen partial pressure in the sputtering device is p≦100 MPa, preferably is set to 2 MPa≦p≦15 MPa.

To increase and set an optimal reproducibility, it is provided that, in a manufacturing process, the layers produced are controlled, at least in a randomly sampled manner, in terms of reproducibility of the structure and layer thickness, in particular by means of Raman spectroscopy.

As an alternative or in addition to this, in a manufacturing process, these layers produced are controlled, at least in a randomly sampled manner, in terms of reproducibility of the structure and layer thickness, also by means of X-ray spectroscopy.

Layer thicknesses that are suitable according to the invention are 50 nm to 20 μm, preferably 75 nm to 8 μm, frequently 100 nm to 4 μm and also frequently 300 nm to 3 μm.

In an advantageous refinement, it is specified that the process parameters can where necessary be adapted using the measurement results obtained by the control measurements. In this way, the control measurements serve not only to control a product for the purpose of quality assurance, but also to adjust the parameters on the basis of the measurement results in order to optimize the manufacturing outcome.

An essential step consists in the spectrometric fractions between anatase and rutile being determined during the Raman spectroscopy and the process parameters being changed such that rutile is predominantly or exclusively generated. In this way, it is possible for there to be a concentration of rutile instead of anatase that can be reproduced using manufacturing technology.

In another advantageous refinement, it is now possible that the spectroscopic results are evaluated automatically and the process parameter changes that are thereupon generated automatically are stored in an adaptive manner and optimized from measurement to measurement. There are thus optimal parameters which renew themselves in a self-learning manner for an optimal manufacturing outcome.

There are now various applications for this. One of these is the coating of lamp housings in this way. Lamp housings within the context of this invention include, in particular, lamp housings which are evacuated or filled with ionizable material.

Another application is the coating of optical elements, such as filters, lenses, mirrors, fiber-optic components and the like in this way.

With regard to a lamp or a light means, the subject matter of the invention is that the lamp vessel is at least partially provided with a rutile coating which is deposited onto the surface that is to be coated at an oxygen partial pressure p by means of sputtering at a deposition temperature of 20 to 300° C. from a titanium target.

With regard to a coating on optical elements such as filters, lenses and mirrors, the subject matter of the invention is that the optical element is at least partially provided with a rutile coating which is deposited onto the surface that is to be coated at an oxygen partial pressure p by means of sputtering at a deposition temperature of 20 to 300° C. from a titanium target.

Advantageously, a multilayer system is applied, at least one layer of which consists predominantly of rutile.

Multilayer coatings have particular optical properties. For instance, multilayer coatings as such are also known, but in the present case the example of embodiment deals with the provision of at least one layer composed of rutile, which in the abovementioned method is applied to the surfaces gently and at relatively low temperatures.

The quality and above all the monitoring of the process is ensured by the fact that the layers produced can be controlled in a manufacturing process, at least in a randomly sampled manner, in terms of reproducibility of the structure and layer thickness, by means of Raman spectroscopy.

As an alternative or in addition to this, it is also possible for the layers produced to be controlled in a manufacturing process, at least in a randomly sampled manner, in terms of reproducibility of the structure and layer thickness, by means of X-ray spectroscopy.

In another advantageous refinement it is provided that the process parameters can where necessary be adapted or automatically adapted using the measurement results obtained.

In both cases, the measured outputs of the measuring devices are linked by information technology to the control of the sputtering system.

Furthermore, it is specified that the spectrometric fractions between anatase and rutile are determined during the Raman spectroscopy and the process parameters are changed such that rutile is predominantly or exclusively generated. In this way, automatic evaluation of Raman spectra may also provide, where necessary, automatic setting of the process parameters for the optimized generation of rutile.

In another advantageous refinement, therefore, it is provided that the spectroscopic results are evaluated automatically and the process parameter changes that are thereupon generated automatically are stored in an adaptive manner and optimized from measurement to measurement.

With regard to a software program product, the subject matter of the invention is that, in a software program product in which the functions and control parameters of the production process for lamps or lights or coatings are stored as control commands of a device on a removable storage medium or in a data-network-enabled data file, and thus can be imported into or exported from the control unit of a sputtering device as control parameters having the specified functions.

The scattering index, also referred to as iHaze, of the transparent titanium dioxide layer according to the invention, after annealing in a furnace at 800° C. for 15 hours, for the still-transparent layer having a layer thickness of 400 nm, has a spectrally integrated Haze (“iHaze”) of ≧0 nm to 80 nm, preferably an iHaze value of 20 nm to 70 nm, more preferably an iHaze value of 30 nm to 60 nm and even more preferably an iHaze value of 40 nm to 50 nm. An optimal layer has no scattering and thus has an iHaze=0 nm. iHaze values of ≧0 nm are therefore most preferred. Further suitable iHaze values are >1 nm, ≧10 nm and ≧15 nm. It should be emphasized that an iHaze value that is as small as possible, from 0 nm to 1 nm, is most preferred.

The titanium dioxide layer according to the invention remains transparent after annealing in a furnace at 800° C. for 15 hours under an ambient air atmosphere.

The invention will be further described with reference to examples of embodiments shown in the drawings to which, however, the invention is not restricted.

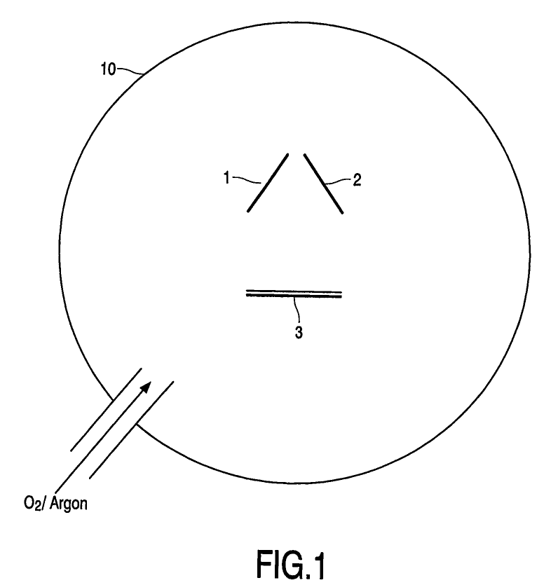

FIG. 1 shows the design of a sputtering device.

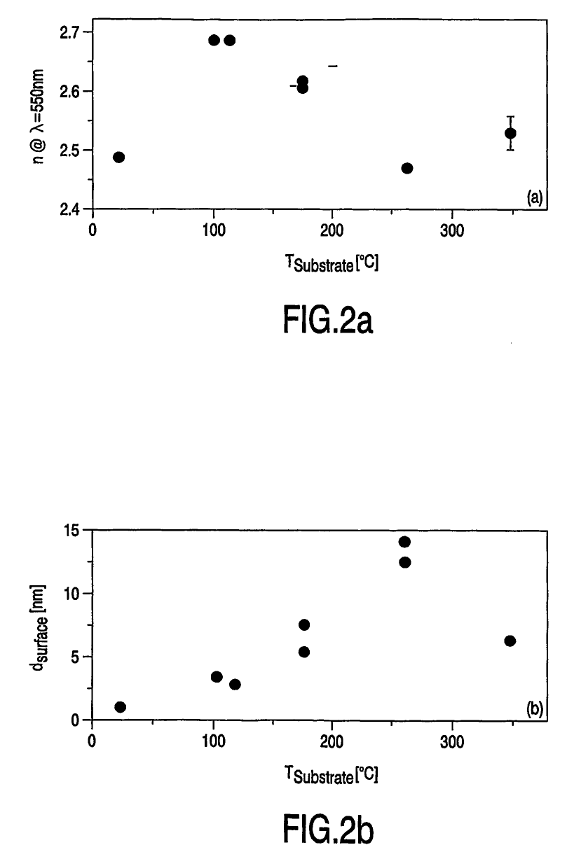

FIG. 2a shows the refractive index of titanium dioxide.

FIG. 2b shows the result with a higher degree of roughness.

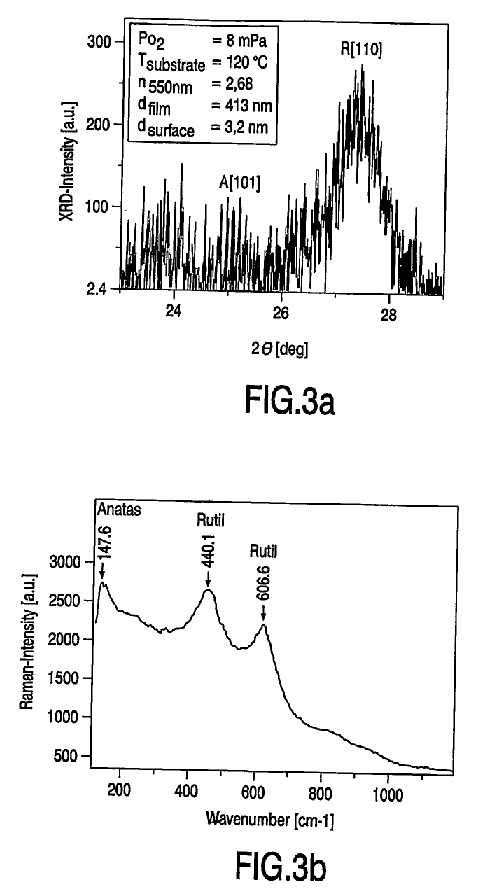

FIG. 3a shows the XRD spectrum.

FIG. 3b shows the Raman spectrum.

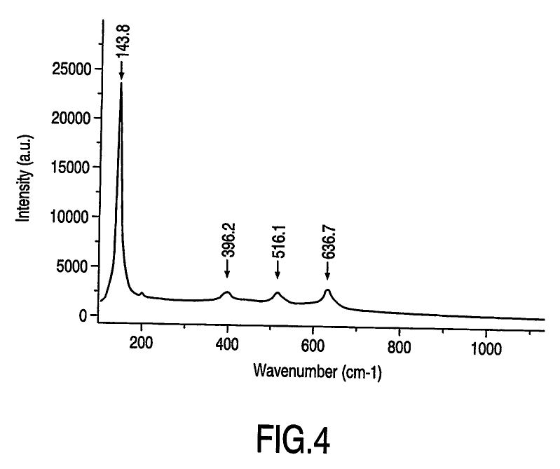

FIG. 4 shows the Raman spectrum.

FIG. 1 shows a design, in principle, of a sputtering system 10. Highly refractive titanium dioxide layers are produced at an excitation frequency of f=40 kHz using a harmonically excited reactive double magnetron sputtering method. Two metal magnetron targets 1, 2 made of titanium, having dimensions of 488 nm×88 nm and being placed edgeways at an angle of 20° to one another, are simultaneously worn down by the method used. The period duration per target is in each case 25 μs. By means of the controlled addition of oxygen as reactive gas, transparent oxidic films form on the substrate 3 shown here. The oxygen partial pressure (p) is p₀₂=8 MPa and the overall pressure is 150 MPa. The coupled-in process power was in the range of 5 to 5.5 kW. The deposited layer thicknesses were about d_{f}=400 nm. The dimensions of the quartz glass substrate used were 50×50 nm. Instead of the planar substrate shown here, lamp vessels or light housings may also be provided as substrate, which are then coated accordingly.

The grounded substrate holder 4 is at a distance of 90 nm from the targets. The horizontal component of the magnetic field across the magnetron at the location of the substrate 3 is about 30 mT. The temperature of a flat heater element 5 fitted behind the substrate 3 is controlled to a defined temperature by means of a PID controller. In this case, the heater is switched on 30 minutes before the start of the process and left on during the coating operation. Besides the heater, the specimen is additionally heated by the action of the plasma during the coating process.

The operating points used for coating were in the so-called “transition mode”. This parameter range, which is usually unstable, is characterized by only partially oxidized targets and also high coating rates. In terms of process technology, it can only be accessed using specific control methods. In the present case, the oxygen partial pressure is controlled via the adapting of the process power and measured using a specifically modified lambda probe.

The layers are optically characterized, for example, by means of ellipsometry. Crystallographic and morphological studies are carried out using Raman and X-ray scattering measurements.

The process conditions used promote the epitaxial growth of very thick, smooth and optically very valuable amorphous layers. The reason for this lies, in particular, in the particularly high ion bombardment that is typical for medium-frequency double magnetron processes. Other coating parameters that are highly relevant in particular for the growth of titanium dioxide are the oxygen partial pressure and the coating temperature.

FIG. 2a shows, as an important optical parameter, the refractive index of titanium dioxide at a wavelength of λ=550 nm as a function of the substrate temperature, brought about by the heater, at the start of the process. It can be seen that at a substrate temperature at the start of the process of about Tₛ=130° C., a maximum of n_{550 nm}=2.7 will pass through in a reproducible manner. In processes without a heating action, typical values of about n_{550 nm}=2.5 arise. At values of Tₛ>about 200° C., the refractive index decreases again significantly and at the same time it is only possible to measure the layers more roughly, as can be seen from the values shown in FIG. 2b. Both the decrease in the refractive index and the increase in roughness are caused by the thermally induced growth of the anatase phase.

FIG. 3 shows the XRD and Raman spectra of the highly refractive specimen produced at a substrate temperature at the start of the process of Tₛ=120° C. The only peak which can be detected in the entire X-ray spectrum is a rutile (110) peak which allows a practically amorphous crystal structure with small embedded rutile crystals to be deduced. The results of the Raman measurement show an equivalent image. Besides a weakly pronounced structure at about χ=148 cm⁻¹ that can be assigned to both the rutile and the anatase phase, clear peaks that can be attributed to the rutile short-range order can be seen.

According to the invention, therefore, by selecting the coating parameters an operating point is defined at which the growth of the anatase phase is not yet possible in terms of the thermal conditions, and in particular is suppressed by the high ion bombardment. The highly refractive layers for a substrate temperature at the start of the process of Tₛ=100 to 200° C. have an amorphous or nanocrystalline structure characterized by a rutile short-range order, which for its part is promoted by the intense ion bombardment. By contrast with the anatase phase, the rutile phase has, in addition to a higher density, also a considerably higher refractive index.

In comparison with FIG. 3b, FIG. 4 shows the Raman spectrum of a TiO₂ specimen which has been produced at a substrate temperature at the start of the process of Tₛ=130° C. and with a considerably lower ion bombardment using a cocurrent sputtering process. All peaks can unambiguously be assigned to the anatase phase.

General Details Regarding the Measurement Conditions
T=23° C. (ambient temperature)
Atmospheric pressure=laboratory air (normal pressure)

Annealing Operation

Annealing in the laboratory air at normal pressure. Annealing duration: in each case 15 hours.

X-ray Diffractometry

In order to be able to make statements regarding phase compositions and particle sizes, X-ray diffractometric measurements were taken using a D5000 diffractometer from Siemens. In this case, a Bragg-Brentano geometry without monochromator was used in the (θ2θ) method. An Ni filter suppressed the CuK_{β} line which arose.

A Cu—K_{α} tube was used as radiation source. Typical measurement parameters were: step size: 2θ=0.020, integration time: Δt=1 s. The beam potential was 40 kV at a beam current of 30 mA. Software from Siemens that was integrated in the measurement software was used for phase assignment.

Haze

The quantification of the scattering level of the specimens is based on the determination of a parameter which is referred to as “Haze”. In this measurement method, the diffusely scattered component of the transmitted electromagnetic radiation is determined using a spectral photometer and standardized to the overall transmitted intensity (Tₜₒₜₐₗ=T_{spec}+T_{diffus}). The Haze in transmission is therefore defined in a range of values between zero and one as

$$Haze ( λ ) = \frac{{T}_{diffus} ( λ )}{{T}_{total} ( λ )} = \frac{{T}_{diffus} ( λ )}{{T}_{diffus} ( λ ) + {T}_{spec} ( λ )} \qquad ( 1 )$$

It should be noted that the measurement curves generally contain intensity modulations on account of interference effects, and these cannot be fully compensated for by means of the standardization. However, their influence can be substantially suppressed by measuring over a broad spectral range.

Using suitable mathematical methods, the respective scattering level of the specimen can be quantified from the data of the spectral measurements. In the present work, the area below the curve in the visible spectral range (λ=380 . . . 800 nm) is for this purpose integrated (“iHaze”) according to equation (2), so that the intensity modulations average out. Since the layer thicknesses of all specimens were set to be about 400±10 nm, there is no need to consider any thickening effect of the scattering. The scattering contribution of the glass substrate on account of any inhomogeneities or incomplete surface cleaning can also be ignored in this evaluation since it falls within the order of magnitude of the measurement accuracy. By means of the spectral integration of the dimensionless parameter “Haze”, the resulting parameter “iHaze” obtains the dimension [length in nm].

$$iHaze = {\int }_{380 nm}^{800 nm} Haze ( λ ) ⅆ λ \qquad ( 2 )$$

Measuring devices: The measurements were carried out using unpolarized light on a Cary 5E spectral photometer from Varian in a spectral range of 350 to 800 nm. In order to measure the diffusely transmitted component T_{diffus}(λ), an Ulbricht globe (“integrating sphere”) was available for this purpose (size of the measurement area: 10×10 nm).

In this case, the directed and unscattered component of the electromagnetic radiation transmitted with a perpendicular radiation incidence is passed out of the measurement globe and guided into a light trap. The scattered signal portion T_{diffus}(λ) is picked up in a globe (diameter 110 nm) coated with PTFE (polytetrafluoroethylene, Lambert radiator) and measured by means of a photodiode protected in a globe from direct irradiation. It is greater the more the specimen scatters the light. On account of the multiple reflections of the light on the inside of the globe, there is the same wavelength-dependent radiation intensity at every point in the volume of the globe. Therefore, on account of the screen, the detector does not measure any direct signal of the specimen or of the directly illuminated globe surface (in the case of an enclosed light trap). If the light trap is covered with a thin barium sulfate layer, then, in addition to the diffuse portion, the directed portion T_{spec}(λ) is also contained in the measured signal. The Haze is calculated in accordance with equation 1.

Ellipsometry

In order to determine the refractive index and layer thickness of the specimens, the measurement method of ellipsometry was used. The method is based on the change in the polarization state of a wave upon reflection on the specimen surface that is under examination. The change in the polarization state is described by the quotient p of the two complex Fresnel reflection coefficients rₚ and rₛ. This can be shown by the relation

$$ρ = \frac{{r}_{p}}{{r}_{s}} = tan Ψ \cdot {e}^{ⅈ Δ} \qquad ( 3 )$$

which is also referred to as the basic ellipsometric equation. Here, Ψ represents the change in the amplitude ratio of the perpendicular and parallel component, and Δ measures the change in phase difference between the two part-waves as a result of the reflection. The subscripts s and p symbolize the part-waves that are polarized perpendicular and parallel to the plane of incidence, respectively. The refractive index was determined according to R. M. A. Azzam, N. M. Bashara, Ellipsometry and polarized light, North Holland, Amsterdam (1987).

If a suitable material model is then defined for the layer/substrate system, in which the properties (optical constants, layer thicknesses) of the material model are linked to the complex reflection coefficients and the measurement parameters (wavelength, angle of incidence), then precise statements can be made about a large number of important film parameters on the basis of the change in the polarization state. The dispersion of the optical constants of the specimens was described using a conventional parameterized Lorentz Oscillator model. This defines the oscillatory behavior of the electrons, which are elastically bound to the solid body atoms, in the event of excitation by means of electromagnetic radiation (see: A. Röseler, Infrared Spectroscopic Ellipsometry, Akademie-Verlag, Berlin (1990)). The specified refractive indices n and n₅₅₀ relate to a wavelength of λ=550 nm and are given to an accuracy of +0.01.

A spectrophotometric ex-situ SE800 ellipsometer from SENTECH Instruments was available for the ellipsometric measurements, said ellipsometer operating in the so-called PCSSA configuration (“Polarizer Compensator Sample Step Scan Analyzer”).

The evaluation was carried out in the spectral range of 380 to 850 nm and at variable angles of incidence of between 55 and 75° (Δ=5°). Conmercially available evaluation software from SENTECH Instruments (“Advanced Fit”), in which a numerical method is integrated in accordance with the simplex algorithm, was available for adapting the measured data to the model.

1. A transparent, thermally stable coating comprising titanium oxide having a rutile structure, characterized in that, at a wavelength of 550 nm, the coating:
has a refractive index of n=2.3 to n=2.75, preferably n=2.4 to n=2.70, more preferably n=2.5 to n=2.65; and/or
after annealing in a furnace at 800° C. for 15 hours, remains transparent and/or has a refractive index of n=2.3 to n=2.75, preferably n=2.4 to n=2.70, more preferably n=2.5 to n=2.65.

2. A transparent coating as claimed in claim 1, characterized in that the coating having a rutile structure and a layer thickness of 400 nm, after annealing in a furnace at 800° C. for 15 hours, remains transparent and has an iHaze of ≧0 nm to 80 nm, preferably 20 nm to 70 nm, more preferably an iHaze of 30 nm to 60 nm and especially preferably an iHaze of 40 nm to 50 nm.

3. A transparent layer as claimed in claim 1, characterized in that the layer is substantially amorphous, preferably is amorphous, and has a rutile-like short-range order structure, with the layer preferably not having any anatase structure.

4. A transparent interference layer for reflecting light within a wavelength range of the transparent spectrum of 250 nm to 5000 nm, preferably 350 to 2500 nm, more preferably 400 to 2000 nm and in particular 420 to 1500 nm, with the layer having one or more first layers and one or more second layers with a refractive index which is lower than that of the one or more first layers, said layers being arranged alternately on a substrate, preferably a transparent substrate, characterized in that the one or more first layers is/are designed as claimed in claim 1.

5. A transparent interference layer as claimed in claim 4, characterized in that, at a wavelength of λ=550 nm, for the one or more second layers the refractive index is n=1.32 to n=2.0, preferably n=1.35 to n=1.80, more preferably n=1.44 to n=1.75.

6. A body having at least one transparent layer and/or transparent interference layer as claimed in claim 1, characterized in that the body is selected from the group comprising beam-forming devices, beam-splitting devices, fiber-optic components, illumination means, in particular lamps, preferably suitable for use in motor vehicles, lamp housings, gas sensors, glasses, in particular insulation glazing, plastics, transparent elements, filters, lenses, mirrors, laser mirrors, in particular transparent filter systems, hot-light mirrors, cold-light mirrors, antireflection systems, band-pass filters, cut-off filters, low-e glazing and/or bodies for electrical applications, such as electrical components, in particular diffusion barriers and/or capacitor elements.

7. A method of producing a transparent, thermally stable, highly refractive coating comprising titanium oxide having a rutile structure, characterized in that the coating comprising titanium oxide is deposited, with the rutile structure being obtained, on the surface of the substrate that is to be coated, at an oxygen partial pressure p which can be defined, by chemical vapor deposition, in particular sputtering, at a deposition temperature of 20 to 300° C. from a titanium target.

8. A method as claimed in claim 7, characterized in that the ion sputtering power density is 1-40 W/cm², preferably 9-15 W/cm² and especially preferably 11-12 W/cm².

9. A method as claimed in claim 7, characterized in that the oxygen partial pressure is p≦100 MPa, in particular p≦10 MPa, preferably 6-10 MPa and especially preferably ≦8 MPa.

10. A method as claimed in claim 7, characterized in that, in a manufacturing process, the layers produced are tested at least in a randomly sampled manner in terms of reproducibility of the structure and of the layer thickness by means of Raman spectroscopy and/or X-ray spectroscopy.
